(19) United States
(12) Patent Application Publication
(10) Pub. No.: US 2006/0099782 A1
(43) Pub. Date: May 11, 2006

(54) Method for forming an interface between germanium and other materials

(75) Inventor: Andrew P. Ritenour, Medford, MA (US)

Correspondence Address: NUTTER MCCLENNEN & FISH LLP, WORLD TRADE CENTER WEST, 155 SEAPORT BOULEVARD, BOSTON, MA, 02210-2604, US

(73) Assignee: Massachusetts Institute of Technology, Cambridge, MA (US)

(21) Appl. No.: 11/251,089

(22) Filed: Oct. 14, 2005

Related U.S. Application Data
(60) Provisional application No. 60/619,294, filed on Oct. 15, 2004.

(51) Int. Cl. H01L 21/22; H01L 21/38

(52) U.S. Cl. 438/542

(57) ABSTRACT

Interfaces that are portions of semiconductor structures used in integrated circuits and optoelectronic devices are described. In one instance, the semiconductor structure has an interface including a semiconductor surface, an interfacial layer including sulfur, and an electrically active layer (e.g., a dielectric or a metal). Such an interface can inhibit oxidation and improve the carrier mobility of the semiconductor structures in which such an interface is incorporated. The interfacial layer can be created by exposure of the semiconductor surface to sulfur donating compounds (e.g., H₂S or SF₆) and, optionally, heating.

### CROSS REFERENCE TO RELATED APPLICATIONS

This application claims the benefit of a U.S. Provisional Application bearing Ser. No. 60/619,294, filed Oct. 15, 2004, the entire contents of which are hereby incorporated herein by reference.

### FIELD OF INVENTION

The technical field of this invention is semiconductor processing and, in particular, treatment of semiconductor surfaces to improve interface properties.

### BACKGROUND OF THE INVENTION

Silicon has traditionally been used for metal-oxide-semiconductor field-effect transistors (MOSFETs). Silicon surfaces are easily passivated by hydrogen and also form a high-quality interface with native insulators such as silicon dioxide (SiO₂). A passivation layer on a semiconductor surface can hinder detrimental chemical reaction of the surface with a material or environment that contacts the surface (e.g., a metal contacting a silicon substrate). Beyond being stable during thermal annealing and chemical processing, the Si—SiO₂ interface also has a low density of interface states (Dᵢₜ<1×10¹¹ cm⁻² eV⁻¹). Other semiconductors, such as germanium, offer higher carrier mobility but lack a high quality native insulator. Additionally, the presence of interfacial states at a semiconductor interface, even when the surface is passivated, can ultimately reduce the overall carrier mobility of a semiconductor device. These disadvantages have prevented germanium from finding wide application in industry.

Apart from the Si—SiO₂ interface which is widely used in the industry at present, there exists a need for techniques for forming high quality interfaces between semiconductors and other materials such as dielectrics and metals. Such techniques would make high performance germanium transistors easier to fabricate and may also be useful for a wide variety of devices, including silicon devices and other semiconductor structures, generally.

### SUMMARY OF THE INVENTION

Methods are described for producing a semiconductor structures having interfaces with reduced interfacial trap densities. In one embodiment, a semiconductor surface that includes germanium can be exposed to a sulfur donating compound under conditions sufficient to form an interfacial layer that includes sulfur. The interface between the semiconductor surface and interfacial layer can have a reduced interfacial trap density relative to an interface between germanium and germanium oxide. An electrically active material can be added to contact the interfacial layer. The combination of the semiconductor surface, interfacial layer, and electrically active material can constitute a least a portion of the semiconductor structure. The methods can also include the step of removing oxide from the semiconductor surface before exposing the surface to the sulfur donating compound.

Sulfur donating compounds can include a sulfur containing fluid, and may be embodied as a composition that includes sulfur hexafluoride, hydrogen sulfide, ammonium sulfide, or any combination of such compositions. The sulfur donating compound can be exposed to the semiconductor surface using any one of chemical vapor deposition, plasma enhanced deposition, molecular beam deposition, and molecular beam epitaxy. Heating can be performed on the sulfur donating compound and/or the semiconductor surface to attain a temperature above ambient temperature.

Semiconductor structures made in accordance with the invention can provide improved overall carrier mobility relative to structures utilizing germanium oxide as the interfacial layer. Semiconductor structures can include diodes, transistors (e.g., a field effect transistor), optoelectronic devices, or portions of such structures. In a particular embodiment, the electrically active material that is added can be a metal. Such an embodiment can be used to form a germanide layer on the semiconductor surface by inducing germanide formation after the metal is added to the interfacial layer. In another particular embodiment, the electrically active material is a high k dielectric material. Such an embodiment can be used to form a gate structure in a device, such as an integrated circuit, by adding a gate material to contact the high k dielectric material.

Other embodiments of the invention are directed to semiconductor structures that can have an interface that includes a semiconductor surface having germanium; an interfacial layer contacting the semiconductor surface; and an electrically active material contacting the interfacial layer. The interfacial layer can include GeSₓ, and can hinder germanium oxide formation. The interface between the semiconductor surface and the interfacial layer can also have a reduced density of interfacial traps relative to an interface between germanium and germanium oxide. The semiconductor structures can have improved overall carrier mobility relative to utilizing germanium oxide as the interfacial layer. As well, embodiments of the invention include semiconductor structures made from any of the methods discussed herein.

Semiconductor surfaces that include germanium can include a single crystal of germanium, which is optionally doped. The Ge:Sₓ ratio in the interfacial layer can be such that x is less than about 4. The thickness of the interfacial layer can be less than about 50 angstroms, or between about 2 angstroms and about 25 angstroms.

Surface treatments to passivate germanium and other semiconductor surfaces to inhibit oxidation, and improve interface properties, are disclosed. The surface treatments are based on exposure of the semiconductor surface to sulfur and, optionally, heating. The invention can be useful in connection with both metal and dielectric depositions onto semiconductor surfaces. The sulfur containing layer can be formed, for example, by treating the semiconductor surface with a sulfur containing liquid or gas, such as H₂S or SF₆.

### BRIEF DESCRIPTION OF THE DRAWINGS

FIG. 1A is a schematic side cross sectional view of an interface of a semiconductor structure, in accord with an embodiment of the invention;

FIG. 1B is a schematic side cross sectional view of a semiconductor surface having an interfacial layer and a layer of an electrically active material, in accord with an embodiment of the invention;

FIG. 1C is a schematic side cross sectional view of an electrically active material layer in contact with an interfacial layer that contact a semiconductor substrate layer, the electrically active layer and interfacial layer are embodied as two discrete regions, in accord with an embodiment of the invention;

FIG. 2A is a schematic side cross sectional view of a germanium surface with oxide removed by a cleaning step as part of a method for forming a gate on a semiconductor structure, in accord with an embodiment of the invention;

FIG. 2B is a schematic side cross sectional view of the germanium surface of FIG. 2A treated with a sulfur donating compound to form an interfacial layer;

FIG. 2C is a schematic side cross sectional view of a layer of high k dielectric material and a layer of gate material added to the structure depicted in FIG. 2B;

FIG. 2D is a schematic side cross sectional view of a gate formed on a germanium substrate after processing the structure depicted in FIG. 2C;

FIG. 3A is a schematic side cross sectional view of a Schottky diode in accord with an embodiment of the invention;

FIG. 3B is a schematic side cross sectional view of a photodiode in accord with an embodiment of the invention;

FIG. 4A is a schematic side cross sectional view of a bipolar junction transistor in accord with an embodiment of the invention;

FIG. 4B is a schematic side cross sectional view of a field effect transistor in accord with an embodiment of the invention;

FIG. 5A is a schematic side cross sectional view of a germanium surface with oxide removed by a cleaning step as part of a method for forming a germanide layer in accord with an embodiment of the invention;

FIG. 5B is a schematic side cross sectional view of the germanium surface of FIG. 5A treated with a sulfur donating compound to form an interfacial layer;

FIG. 5C is a schematic side cross sectional view of a layer of metal added to the structure depicted in FIG. 5B;

FIG. 5D is a schematic side cross sectional view of a germanide layer formed from the structure depicted in FIG. 5C;

FIG. 6 depicts a graph of intensity versus binding energy for two X-ray photoelectron spectroscopy experiments performed on a pair of germanium surfaces that are acid cleaned, one of the surfaces is treated with ammonium sulfide, in accord with an embodiment of the invention, and the other is not sulfide treated; and

FIG. 7 depicts a graph of current versus voltage for a pair of Schottky diodes, one of the diodes has a germanium surface treated with ammonium sulfide, in accord with an embodiment of the invention, and the other diode has a germanium surface that is not sulfide treated.

### DETAILED DESCRIPTION OF THE INVENTION

Embodiments of the invention are directed to interfaces of semiconductor structures, and methods of forming semiconductor interfaces. The semiconductor structure includes an interface having a layer containing sulfur. Such interfacial layers can enhance the properties of the semiconductor structure (e.g., enhancing the overall carrier mobility of the structure, stabilizing passivation of the semiconductor material, or reducing interfacial trapped charge density). Though specific embodiments of the invention are directed toward using germanium as a semiconductor material, and thus germanium interfaces with other layers and materials, it is understood that the devices and methods discussed herein also have applicability to other semiconductor materials.

The term “semiconductor structure” as used herein includes electronic devices, integrated circuit structures, and optoelectronic devices and structures that utilize a semiconductor material.

The term “interface” as used herein refers to the meeting region of two or more materials. An interface can refer to the contact point or area where the materials meet. As well, an interface can include a continuous or discontinuous layer that is interstitial between the materials. The layer can include a composition or can even be empty space between the materials.

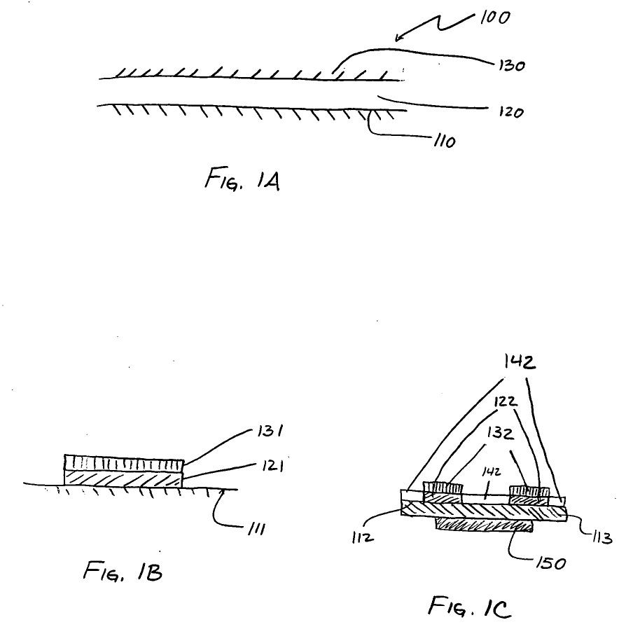

One embodiments of the invention is directed to an interface of a semiconductor structure, as exemplified in FIG. 1A. The interface 100 includes an interfacial layer 120 contacting a semiconductor surface 110. The interfacial layer includes sulfur. An electronically active material 130 contacts the layer 120 opposite from the semiconductor surface 110. In a particular embodiment, the semiconductor surface includes germanium, and the interfacial layer includes GeSₓ, GeSₓ representing the stoichiometric ratio of germanium to sulfur in at least a portion of the interfacial layer.

Semiconductor structures, which have an interfacial layer that includes sulfur, can be associated with one or more of the following properties. In one instance, the interfacial layer acts as a passivating layer to hinder the formation of oxide on the semiconductor surface. For example, an interfacial layer with GeSₓ can act to hinder the formation of germanium oxide on the germanium surface. Germanium oxide can adversely affect the performance of a semiconductor structure due to oxide's instability as a result of its water solubility and sensitivity to temperature. The presence of a sulfur containing interfacial layer can hinder the oxide formation on the germanium surface, and potentially prevent problems associated with the oxide's presence.

In another instance, the interfacial layer can improve the overall carrier mobility of a semiconductor structure. Semiconductor interfaces can accumulate interfacial traps that trap electrons or holes in the region of the interface, and thus reduce the overall carrier mobility of the device. This problem is of particular note at interfaces of germanium and germanium oxide where the interfacial trap density (i.e., the number of interfacial traps per unit area) is actually greater than that at silicon and silicon dioxide interfaces. Thus, even though germanium as a material has a higher carrier mobility, the overall carrier mobility of devices made with a germanium oxide interface can be lower because of the high density of such traps. Indeed, even the use of passivating layers on germanium surfaces such as germanium oxynitride, aluminum nitride, and hafium nitride can still result in a poor semiconductor structure because the interface of the germanium surface and the aforementioned named passivating layers still have a large number of interfacial traps. Since an interfacial layer having GeSₓ on a germanium surface has a lower density of interfacial traps relative to a germanium/germanium oxide interface, the overall carrier mobility of a semiconductor structure can be improved.

In another instance, the interfacial layer can reduce the density of dangling bonds at the semiconductor surface. The presence of incompletely bonded atoms at a semiconductor surface can act as interfacial traps that degrade the carrier mobility in the surface region. An interfacial layer including sulfur can allow atoms in the layer to bond with the unbound germanium atoms of the surface by forming Ge—S bonds, thus potentially alleviating the presence of an interfacial trap.

Semiconductor surfaces may be constructed from a variety of materials. Embodiments of the invention are particularly directed to the use of germanium in the semiconductor surface. Though surfaces of a single crystal of germanium are particularly utilized in some embodiments, the techniques and devices described herein may utilize other germanium surfaces in which the germanium is in a different disposition (e.g., the semiconductor surface may be a portion of a germanium alloy or a portion of a polycrystalline germanium material). No particular orientation of the crystal structure surface is necessarily preferred (e.g., <100>, <111>, or <110>). Semiconductor surfaces may also include surfaces of a semiconductor that are doped with one or more components in one or more regions. Such doping can induce charge carriers utilized in the semiconductor structure. For example, when germanium is used as the semiconductor, doping with a pentavalent impurity such as arsenic, antimony, bismuth, or phosphorous can form an n-type semiconductor, or doping with a trivalent impurity such as aluminum, gallium, indium, or boron can form a p-type semiconductor. The doping may occur in one or more regions of the semiconductor surface to form a particular structure (e.g., a PNP device or a NPN device).

Interfacial layers can impart one or more of the properties previously discussed to semiconductor structures in which they are utilized (e.g., reducing interfacial trap densities or reducing dangling bond density at a semiconductor surface). The interfacial layer can be less than a monolayer, or up to several monolayers thick. In a particular embodiment, the interfacial layer has a thickness less than about 50 angstroms, and is more particularly about 2 angstroms to about 25 angstroms thick. As mentioned previously, the interfacial layer can include GeSₓ when the semiconductor surface includes germanium. Though the value of x is not necessarily restricted, x is less than about 4 in a particular embodiment of the invention.

Electrically active materials are materials that act as charge conductors and/or have a tendency to build up limited surface charge when exposed to an electric field. Particular embodiments utilize materials that are good conductors (e.g., a metal) or high k dielectric materials. Examples include materials used to make electrical contacts for germanium such as titanium, platinum, nickel, and aluminum. Typical high k materials include HfO₂, ZrO₂, LaAlO₃ and other oxide and materials known to those skilled in the art.

Generally, the semiconductor surface, interfacial layer, and the electrically active material are sized, shaped and configured to construct structures utilized in electronic devices and other applications where semiconductors are utilized. FIGS. 1B and 1C depict exemplary configurations for the interface of a semiconductor structure. FIG. 1B shows a semiconductor surface 111 contacting an interfacial layer 121. The interfacial layer 121 isolates a layer of electrically active material 131. FIG. 1C shows a discrete semiconductor layer 113 having a semiconductor surface 112 contacting an interfacial layer 122 configured as two discrete segments. Two electrically active material layers 132 contact the interfacial layers 122 correspondingly. Layers 142 are also utilized further isolate the semiconductor surface 112. An electrode 150 is attached to the opposite side of the semiconductor layer 113 from the interfacial layers 122. Accordingly, substrates that may be used to form the semiconductor surface, interfacial layer, and electrically active material can be configured as a continuous or discrete block structure, or a continuous or discrete layer structure, the layer attached to another substrate.

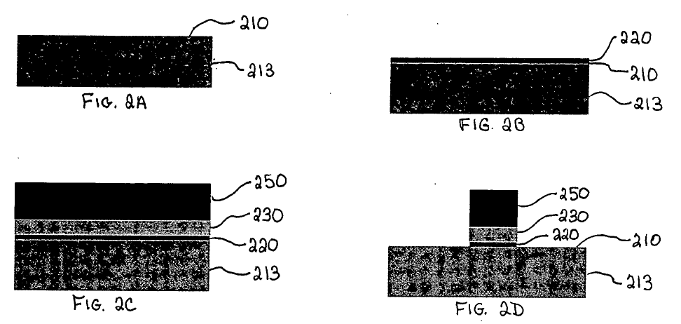

In a particular embodiment, an interface is configured as a semiconductor gate structure shown in FIG. 2D. A germanium substrate 213 has a surface 210 that contacts an interfacial layer 220 having GeSₓ. Opposite the contact surface with the germanium substrate 210, the interfacial layer 220 contacts a high k dielectric material 230. A layer of gate material 250 contacts the high k dielectric material 230. Gate materials that can be utilized include the range of materials utilized in conjunction with high k dielectrics, such as platinum, titanium, palladium, and ruthenium, TiN, TaN, WN, among others. The interfacial layer of the gate structure can enhance the performance of semiconductor devices such as N-MOSFETs using germanium as the semiconductor, as described in more detail below.

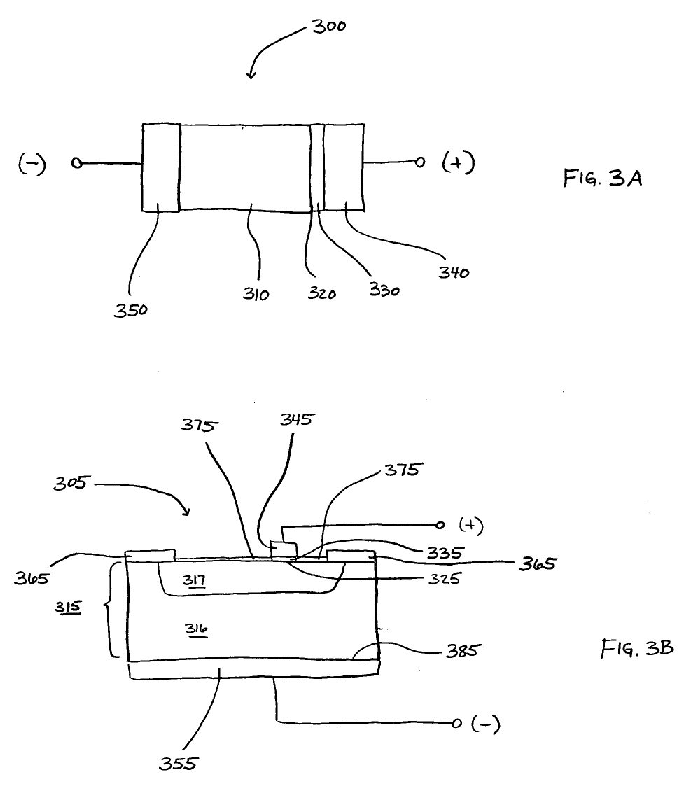

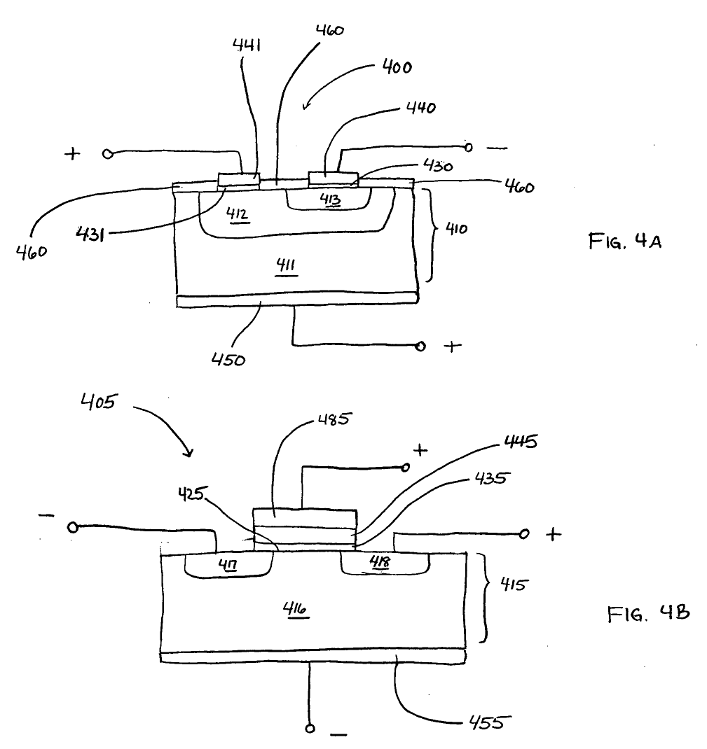

The various configurations of a semiconductor interface can be utilized in a variety of semiconductor structures. Some examples of such semiconductor structures include the diodes depicted in FIGS. 3A and 3B, and the transistors depicted in FIGS. 4A and 4B. However, it is clear that the use of such interfaces may be utilized in other semiconductor structures and optoelectronic devices, and that the structures depicted in FIGS. 3A, 3B, 4A, and 4B are merely particular examples of devices that can be optionally configured in a variety of manners as known to those skilled in the art.

FIG. 3A is a schematic diagram of a Schottky diode consistent with an embodiment of the invention. The diode 300 includes a germanium substrate 310 having an interfacial layer 330 contacting one end of the substrate 310. The interfacial layer 330 includes sulfur The germanium substrate 310 can be doped to be N-type or P-type, and is typically a single crystal substrate. A conducting material 340 contacts the interfacial layer 330, and acts as the anode. Another conductor 350 is attached at the other end of the diode 300 acting as a cathode. An Ohmic contact is typically utilized here. For example, highly doping the substrate 310 adjacent to the cathode 350 can thin the depletion region such that electron tunneling is enhanced. When the diode is forward biased (e.g., a positive potential is applied to the anode), current flows through the diode. Utilizing an interfacial layer 330 having sulfur can decrease the interfacial trap density at the germanium surface 320, which can improve carrier transport from the germanium substrate 310 to the anode 340. Optionally, an interfacial layer having sulfur can also be positioned between the cathode 350 and the substrate 310 to also reduce interfacial traps at a cathode/substrate interface.

FIG. 3B is a schematic diagram of an optoelectronic, a photodiode 305, consistent with an embodiment of the invention. The device 305 utilizes a single crystal germanium substrate 315 that is doped into a N-region 316 and a P-region 317. The cathode 355 is attached to the one end of the substrate 315, while the anode 345 is coupled to the substrate 315 with interfacial layer 335 posed between the anode 345 and the surface 325 of the germanium substrate 315. An antireflection coating 375 covers a portion of the surface 325 that is P-doped to reduce light reflection in a particular wavelength range, while insulating layer 365 covers the remainder of the surface 325. When the photodiode 305 is reverse biased (e.g., a positive potential is applied to the cathode), a depletion region grows in the substrate 315 between the surfaces 325, 385. Photons striking the active region of the photodiode surface 325 (i.e., the portion covered by the antireflective coating 375) cause the creating of electron hole pairs in the substrate 315 that migrate from the depleted region, which results in current flow. The presence of an interfacial layer 335 having sulfur can improve the performance of the photodiode by reducing the potential of carrier flow to be disrupted by the presence of interfacial traps at the interface between the interfacial layer 335 and the substrate 315. Likewise, an interfacial layer having sulfur can also be used at interface 385 to improve transport properties of carriers.

Another embodiment of a semiconductor structure is a bipolar junction transistor 400, as exemplified in FIG. 4A as an NPN transistor. A single crystal germanium substrate 410 is doped to have two N-type regions 411, 413 and a P-type region 412. An aluminum emitter contact 440 is coupled over the N-type region 413, an interfacial layer 430 having sulfur being present between the contact 440 and the N-type region 413. An aluminum base contact 441 contacts an interfacial layer 431 having sulfur, the layer 431 contacting the germanium substrate's P-type region 412. An insulating layer 460 covers the remainder of the surface of the substrate 410. A collector contact 450 is attached to the end of the substrate 410 opposite the end having a surface shared by the N-type region 413 and P-type region 412. In typical operation, when a positive potential is applied to the emitter 440 contact relative to the base contact 441 and a positive potential is applied to the base contact 441 relative to the collector contact 450, carriers in the substrate 410 tend to move from the N-type region 413 to the P-type region 412 then to the N-type region 411. The presence of interfacial layers 430, 431 with sulfur reduces the density of interfacial traps that can hinder carrier flow through the transistor 400. An interfacial layer having sulfur may also be utilized between the substrate 410 and the collector contact 450.

An embodiment of a semiconductor structure as a field effect transistor is exemplified in FIG. 4B. A single crystal germanium substrate 415 is doped into two N-type regions 417, 418 and a P-type region 416. An interfacial layer 435 having sulfur contacts a surface of the substrate that includes the two N-type regions 417, 418 and the P-type region 416. A high k dielectric layer 445 is positioned over the interfacial layer 435. A conductive contact 485 is positioned over the dielectric layer 445. The combination of the high k dielectric layer 445 and the conductive contact 485 form a gate. A ground contact 455 is coupled to the bottom of the substrate 455. In operation, a positive potential drop between the drain N-type region 418 and the source N-type region 417 induces carrier mobility from one region 417 to another 418 in a thin layer region of the substrate 415 adjacent to the surface 425. A positive potential is applied to the contact 485. The high k dielectric layer 445 insulates the contact 485 from the substrate 415, setting up an electric field at the interface 425. The use of a high k dielectric allows the use of stronger electric fields to control carrier leakage, while reducing the tunneling problems associated with other configurations. By utilizing an interfacial layer 435 having sulfur between the surface 425 and the high k dielectric layer 445, the density of interfacial traps can be reduced, resulting in better carrier mobility in the region of the substrate 415 adjacent to the surface 425. Optionally, an interfacial layer including sulfur may also be utilized between the ground contact 455 and the substrate 415.

Other embodiments of the invention are directed to methods of forming semiconductor structures having an interface that includes sulfur. In an exemplary embodiment, a semiconductor surface is exposed to a sulfur donating compound under conditions sufficient to form an interfacial layer having sulfur that contacts the semiconductor surface. An electrically active material is subsequently added to the interfacial layer to form the semiconductor structure or a portion thereof. The interfacial layer can act to provide any combination of the functions of an interfacial layer as discussed previously (e.g., when a germanium surface is utilized, an interfacial layer can act to hinder the formation of germanium oxide and/or reduce the density of trap carriers at a germanium surface interface and/or reduce the number of dangling bonds associated with a germanium surface).

Techniques utilized to expose semiconductor surfaces to particular compounds, or to add electrically active materials, include a variety of deposition techniques. For example, sulfur donating compounds can be exposed to a semiconductor surface, such as a single crystal germanium surface, using any one, or more, of chemical vapor deposition, plasma enhanced deposition, molecular beam deposition, and molecular beam epitaxy. Sulfur donating compounds may be heated above ambient temperature during or after exposure to a semiconductor surface to promote forming an interfacial layer (e.g., the sulfur donating compound may be heated itself to a temperature in the range of about 60° C. to about 80° C., and/or the semiconductor surface may be heated to transfer thermal energy to the deposited material). As well, the pressure of the environment during exposure may be adjusted to be above, at, or below atmospheric to promote deposition and/or interfacial layer formation (e.g., use of low pressure chemical vapor deposition can utilize pressures substantially below atmospheric pressure). In general, electronics manufacturing techniques such as deposition, lithography, masking, etching, spin coating and others known to those skilled in the art of semiconductor and optoelectronic manufacturing can be used to perform particular steps of the methods, or may be used to augment methods consistent with embodiments of the invention. For example, the use of etching and masking allows deposited layers and substrates to be sized and shaped to form the semiconductor gates as depicted in FIG. 2P.

The types of compositions utilized in various steps of the disclosed methods include those resulting in the formation of the interfacial layers and electrically active materials discussed herein. For example, sulfur donating compounds include sulfur containing fluids (e.g., gases or liquids). Specific examples of sulfur donating compounds or fluids include compounds containing any one of ammonium sulfide, hydrogen sulfide, sulfur hexafluoride, or a combination of the named compounds.

Since elimination of germanium oxide at an interface with a germanium surface can be advantageous in some semiconductor structures, some embodiments include treating a germanium surface to remove oxide from the surface before exposing the surface to the sulfur donating compound. Upon removal of the oxide, the germanium surface is exposed to the sulfur donating compound to form the sulfur containing interfacial layer before the oxide can substantially reform on the semiconductor surface. Acids, such as hydrogen fluoride or hydrogen chloride in a mixture with water, can be used to remove the oxide. As well, oxide can be removed from the surface under ultra high vacuum conditions at about 400° C. Utilization of the ultra-high vacuum removal technique allows subsequent in-situ formation of the interfacial layer by exposing the surface to H₂S.

In another embodiment, a method of forming an interface of a semiconductor structure includes adding an additional material to contact the electrically active material. Such a method can be used to formulate a gate structure as utilized in a field effect transistor as depicted in FIG. 4B. A particular example is depicted in FIGS. 2A-2D. A surface 210 of a single crystal germanium substrate 213 is cleaned to remove oxide from the surface, as shown in FIG. 2A. The substrate 213 is then exposed to a sulfur donating compound to form an interfacial layer with GeSₓ 220 on the substrate 213, as shown in FIG. 2B. Next, a high k dielectric material is added 230, followed by the addition of a gate material 250 to form the layered structure in FIG. 2C. A mask is applied, followed by etching, to form the specific gate structure shown in FIG. 2D. Thermal annealing in an inert or reactive environment may also be performed after sulfur treatment, dielectric deposition, and/or gate material deposition to improve the interface properties. When the method is applied to an appropriately doped germanium substrate, the field effect transistor shown in FIG. 4B can be produced.

Other embodiments of the invention are directed toward a semiconductor structure having a germanide layer on a germanium surface. Such germanide layers can act as Ohmic contacts in a transistor or be used as a portion of diodes or other semiconductor and optoelectronic structures. The germanide layer can also be used as a rectifying contact (Schottky-like) in various semiconductor and optoelectronic devices such as a MOSFET. The germanide layer is formed from an interfacial layer having sulfur and a metal. Possible metals to be used include nickel, titanium, cobalt, platinum, palladium, and ruthenium. The original interfacial layer can act to hinder the formation of an oxide layer that is detrimental to germanide formation. The germanide layer may be used with electrically active materials and insulators to form portions of a more complex semiconductor structure.

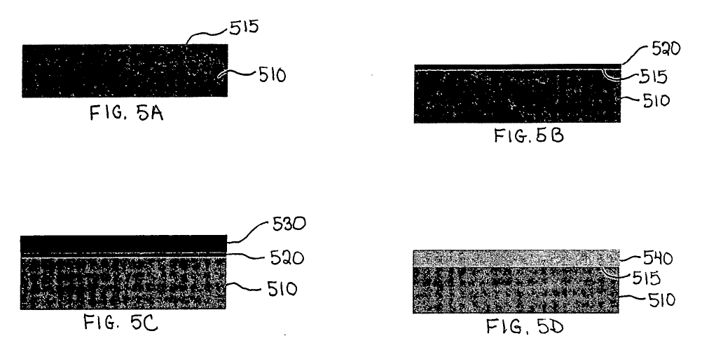

A method for forming the germanide layer is depicted in FIGS. 5A-5D. A germanium substrate 510 is cleaned to remove oxide from a surface 515, as shown in FIG. 5A. The substrate surface 515 is then exposed to a sulfur donating compound to form an interfacial layer 520 having GeSₓ on the surface 515, as shown in FIG. 5B. A metal layer 530 is added to the interfacial layer 520. Germanide formation is then induced to form the germanide layer 540 on the surface 515 shown in FIG. 5D. Germanide formation can be induced utilizing any of the techniques known in the art. For example, germanide formation is induced by annealing the metal, interfacial layer, and germanium surface (e.g., heating the interface to induce germanide formation). The method can include the optional step of removing unreacted metal after inducing germanide formation (e.g., etching the unreacted metal using a composition such as a hydrohalide).

### EXAMPLES

The following examples are provided to illustrate some embodiments of the invention. The examples are not intended to limit the scope of any particular embodiment(s) utilized.

### Example 1

### Germanium Schottky Diodes

Schottky diodes were produced using crystal germanium substrates. Surfaces of the substrates were cleaned by cyclically exposing the surfaces to either hydrogen fluoride or hydrogen chloride, followed by a deionized water (DI water) rinse, to remove the presence of germanium oxide. The surfaces were subsequently exposed to a ammonium sulfide ((NH₄)₂S) solution at a temperature between 60° C. and 70° C. for 20 minutes to form interfacial layers on the surfaces. The layers were again rinsed with DI water. Evaporated titanium is then deposited on the interfacial layers to form the Schottky diodes.

### Example 2

### Interfacial Layer Hinderance of Germanium Oxide Formation

The effect of the interfacial layer in hindering oxide formation was examined using X-ray photoelectron spectroscopy (XPS). Two surfaces were tested using XPS. A control surface of germanium was prepared by immersing the surface in a solution having a 4:1 ratio of DI water to hydrogen chloride. A sulfur treated surface of germanium was prepared by utilizing the hydrogen chloride procedure for the control surface, followed by immersing the surface in a 20% solution of ammonium sulfide at 65° C. for 20 minutes. The surface was subsequently cleaned with DI water. XPS was then conducted on each surface to detect the presence of germanium oxide. XPS impinges photons on a surface to excite and cause photoelectrons to be ejected from the surface. The photoelectrons are collected and their individual energies are determined, the spectra determining the nature of the material surface. For the measurements conducted here the photon energy is Al K_{α} (1486.6 eV).

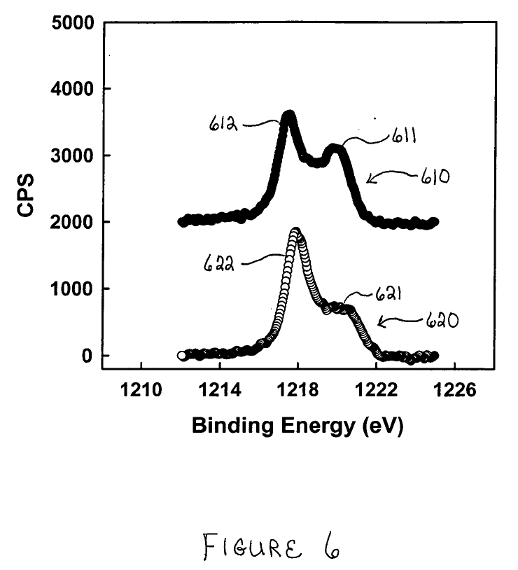

The results of the XPS trace on each surface is shown in FIG. 6. Trace 610 shows the spectra from the control surface. Trace 620 shows the spectra from the sulfur treated surface. The ratio of the magnitudes of the trace at about 1218 eV and 1221 eV indicate the relative ratio of Ge to GeO₂ on the surface. A visual comparison of the ratio of the magnitude of peak 612 to peak 611 as compared to the ratio of the magnitude of peak 622 to peak 621 indicates the substantially reduced amount of oxide in the sulfur treated sample, as opposed to the control sample.

### Example 3

### Comparing IV Characteristics of Schottky Diodes

Two Schottky diodes were manufactured and their current vs. voltage (IV) characteristics compared. Two germanium substrates were cleaned using dilute hydrofluoric acid. One of the substrates was subsequently immersed in ammonium sulfide at 65° C. for 20 min. The other substrate, acting as a control, was not exposed to sulfur. Both substrates were then loaded into an e-beam evaporator and platinum electrodes were shadow masked onto the germanium substrates. Aluminum was evaporated onto the back of the samples for backside electrical contact. The platinum electrode area was 1.95 E-3 cm².

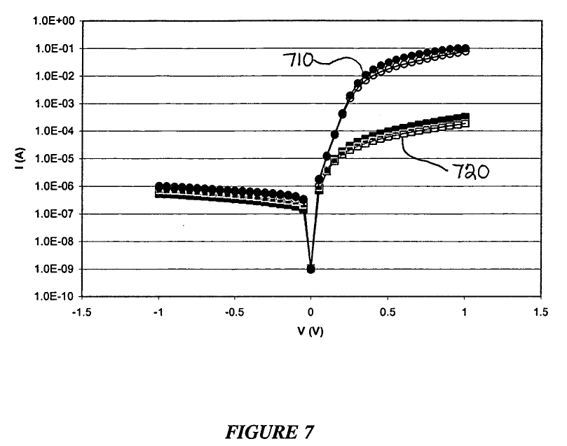

FIG. 7 shows current vs. voltage characteristics for each of the devices. Trace 710 shows the current vs. voltage characteristics of the sulfur-treated device, while trace 720 shows the characteristics of the control device. Under conditions of forward biasing, the sulfur treated device has improved current transmission at a given voltage relative to the control device.

While the present invention has been described in terms of specific methods, structures, and devices it is understood that variations and modifications will occur to those skilled in the art upon consideration of the present invention.

Those skilled in the art will appreciate, or be able to ascertain using no more than routine experimentation, further features and advantages of the invention based on the above-described embodiments. Accordingly, the invention is not to be limited by what has been particularly shown and described, except as indicated by the appended claims. All publications and references are herein expressly incorporated by reference in their entirety.

1. A method of producing a semiconductor structure having an interface with a reduced interfacial trap density, the method comprising:
exposing a surface of a semiconductor comprising germanium to a sulfur donating compound under conditions sufficient to form an interfacial layer comprising sulfur with an interface between the semiconductor surface and interfacial layer having reduced interfacial trap density relative to an interface of germanium and germanium oxide; and
adding an electrically active material to contact the interfacial layer comprising sulfur;
the semiconductor surface, interfacial layer, and electrically active material forming at least a portion of a semiconductor structure.

2. The method of claim 1, wherein the semiconductor structure produced by the method has improved carrier mobility relative to a structure utilizing germanium oxide as the interfacial layer.

3. The method of claim 1 further comprising:
removing oxide from the semiconductor surface before exposing the surface to the sulfur donating compound.

4. The method of claim 1, wherein the step of exposing the semiconductor surface includes exposing the semiconductor surface to a sulfur containing fluid.

5. The method of claim 1, wherein the sulfur donating compound includes at least one of sulfur hexafluoride, hydrogen sulfide, and ammonium sulfide.

6. The method of claim 1, wherein the step of exposing the semiconductor surface includes heating at least one of the sulfur donating compound and the semiconductor surface to a temperature above ambient temperature

7. The method of claim 1, wherein the step of exposing the semiconductor surface includes exposing the semiconductor surface to a sulfur-donating compound by at least one of chemical vapor deposition, plasma enhanced deposition, molecular beam deposition, and molecular beam epitaxy.

8. The method of claim 1, wherein the method is used to create at least a portion of a diode.

9. The method of claim 1, wherein the method is used to create at least a portion of a transistor.

10. The method of claim 1, wherein the method is used to create at least a portion of an optoelectronic device.

11. The method of claim 1, wherein the step of adding the electrically active material includes adding a metal.

12. The method of claim 10 further comprising:
inducing the formation of a germanide layer contacting the semiconductor surface after adding the metal.

13. The method of claim 1, wherein the step of adding the electrically active material includes adding a high k dielectric material.

14. The method of claim 12 further comprising:
adding a gate material to contact the high k dielectric material.

15. A semiconductor structure having an interface comprising:
a semiconductor surface comprising germanium;
an interfacial layer contacting the semiconductor surface, the interfacial layer comprising GeSₓ; the interfacial layer hindering germanium oxide formation; and
an electrically active material contacting the interfacial layer.

16. The semiconductor structure of claim 14, wherein an interface between the semiconductor surface and the interfacial layer has a reduced density of interfacial traps relative to an interface between germanium and germanium oxide.

17. The semiconductor structure of claim 14, wherein the semiconductor structure has improved carrier mobility relative to a structure utilizing germanium oxide as the interfacial layer.

18. The semiconductor structure of claim 14, wherein the semiconductor surface comprises a single crystal of germanium.

19. The semiconductor structure of claim 18, wherein the single crystal of germanium is doped.

20. The semiconductor structure of claim 14, wherein x is less than about 4.

21. The semiconductor structure of claim 14, wherein the interfacial layer has a thickness less than about 50 angstroms.

22. The semiconductor structure of claim 14, wherein the layer has a thickness between about 2 angstroms and about 25 angstroms.

23. The semiconductor structure of claim 14, wherein the electrically active material is a metal.

24. The semiconductor structure of claim 14, wherein the electrically active material is a high k dielectric material.

25. The semiconductor structure of claim 24 further comprising:
a gate material contacting the high k dielectric material, the gate material being separated from the semiconductor surface.

26. The semiconductor structure of claim 14, wherein the semiconductor structure comprises at least a portion of a transistor.

27. The semiconductor structure of claim 14, wherein the semiconductor structure comprises at least a portion of a field effect transistor.

28. The semiconductor structure of claim 14, wherein the semiconductor structure comprises at least a portion of a diode.

29. The semiconductor structure of claim 14, wherein the semiconductor structure comprises at least a portion of an optoelectronic device.
